(19) United States
(12) Patent Application Publication
(10) Pub. No.: US 2024/0162391 A1
(43) Pub. Date: May 16, 2024

(54) LUMIPHORIC MATERIAL ARRANGEMENTS FOR COVER STRUCTURES OF LIGHT-EMITTING DIODE PACKAGES

(71) Applicant: CreeLED, Inc., Durham, NC (US)

(72) Inventor: Colin Blakely, Raleigh, NC (US)

(21) Appl. No.: 18/055,934

(22) Filed: Nov. 16, 2022

(51) Int. Cl. H01L 33/50; H01L 27/15; H01L 33/54

(52) U.S. Cl. CPC H01L 33/504; H01L 27/15; H01L 33/54

(57) ABSTRACT

Solid-state lighting devices including light-emitting diodes (LEDs) and, more particularly, lumiphoric material arrangements for cover structures of packaged LED devices are disclosed. Lumiphoric material arrangements include discrete regions of lumiphoric materials that are provided over portions of underlying LED chips. The discrete regions of lumiphoric materials may be patterned on portions of cover structures that are then attached to underlying LED chips. By having discrete regions of lumiphoric materials over portions of LED chips, certain emissions from the LED chips may pass through the lumiphoric materials while other emissions from the LED chips may be emitted without passing through the lumiphoric materials. In this manner, contributions of the lumiphoric materials to aggregate emissions of LED packages may provide increased spectral bandwidth. The ability to provide patterns of lumiphoric materials on cover structures provides increased control of intensity and/or spatial position of the lumiphoric materials relative to the aggregate emissions.

### FIELD OF THE DISCLOSURE

The present disclosure relates to solid-state lighting devices including light-emitting diodes (LEDs), and more particularly to lumiphoric material arrangements for cover structures of packaged LED devices.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new display applications and are being increasingly utilized for general illumination applications, often replacing incandescent and fluorescent light sources.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from silicon carbide, gallium nitride, gallium phosphide, aluminum nitride, gallium arsenide-based materials, and/or from organic semiconductor materials. Photons generated by the active region are initiated in all directions. Lumiphoric materials may be arranged that convert at least some light generated from the active regions of LED chips to a different wavelength.

LED packages have been developed that provide mechanical support, electrical connections, and encapsulation for LED emitters and lumiphoric materials. As LED technology continues to advance, LED packages are needed that emit light of high color quality for various applications in small sizes. Despite recent advances in LED package technology, there can still be challenges in producing high quality light with desired emission characteristics while also providing high light emission efficiency in LED packages.

The art continues to seek improved LEDs and solid-state lighting devices having desirable illumination characteristics capable of overcoming challenges associated with conventional LED devices.

### SUMMARY

The present disclosure relates to solid-state lighting devices including light-emitting diodes (LEDs), and more particularly to lumiphoric material arrangements for cover structures of packaged LED devices. Lumiphoric material arrangements include discrete regions of lumiphoric materials that are provided over portions of underlying LED chips. The discrete regions of lumiphoric materials may be patterned on portions of cover structures that are then attached to underlying LED chips. By having discrete regions of lumiphoric materials over portions of LED chips, certain emissions from the LED chips may pass through the lumiphoric materials while other emissions from the LED chips may be emitted without passing through the lumiphoric materials. In this manner, contributions of the lumiphoric materials to aggregate emissions of LED packages may provide increased spectral bandwidth. The ability to provide patterns of lumiphoric materials on cover structures provides increased control of intensity and/or spatial position of the lumiphoric materials relative to the aggregate emissions.

In one aspect, an LED package comprises: a submount; an LED chip on the submount, the LED chip comprising a first face and a second face that opposes the first face, the first face being positioned closer to the submount than the second face; and a cover structure arranged over the LED chip, the cover structure comprising a lumiphoric material region that is vertically registered over a first portion of the LED chip, the first portion of the LED chip comprising a smaller area than the first face of the LED chip. In certain embodiments, the cover structure comprises a support element with a top surface and a bottom surface that opposes the top surface, the bottom surface being arranged closer to the LED chip than the top surface, and wherein the lumiphoric material region is arranged on the bottom surface of the support element. The LED package may further comprise a transparent material region on portions of the support element that are laterally adjacent the lumiphoric material region. In certain embodiments, a surface of the transparent material region that is proximate the LED chip is coplanar with a surface of the lumiphoric material region that is proximate the LED chip. In certain embodiments, the lumiphoric material region occupies a range of 1% to 50% of the bottom surface of the support element. In certain embodiments: the LED chip is configured to provide light with a first peak wavelength in a range from 430 nanometers (nm) to 480 nm; and the lumiphoric material region is configured to convert a portion of the first peak wavelength to a second peak wavelength that is in a range from 480 nm to 570 nm. In certain embodiments, the lumiphoric material region comprises a plurality of discrete portions that forms a repeating pattern across the cover structure. In certain embodiments, the lumiphoric material region comprises a plurality of discrete portions that forms a random pattern across the cover structure. The LED package may further comprise a shutter that is configured to selectively cover the lumiphoric material region

In another aspect, an LED package comprises: a submount; a first LED chip on the submount; a first cover structure arranged over the first LED chip, the first cover structure comprising a first lumiphoric material region that is vertically registered over only a portion of the first LED chip; a second LED chip on the submount; and a second cover structure arranged over the second LED chip, the second cover structure comprising a second lumiphoric material region that is vertically registered over only a portion of the second LED chip. In certain embodiments, the first lumiphoric material region and the second lumiphoric material region comprise a same type of lumiphoric material. In certain embodiments, the first lumiphoric material region is arranged in a first pattern on the first cover structure and the second lumiphoric material region is arranged in a second pattern on the second cover structure, wherein the first pattern is different than the second pattern. In certain embodiments: the first LED chip and the second LED chip are configured to provide light with a first peak wavelength in a range from 430 nm to 480 nm; and the first lumiphoric material region and the second lumiphoric material region are configured to convert a portion of the first peak wavelength to a second peak wavelength that is in a range from 480 nm to 570 nm. The LED package may further comprise: a third LED chip on the submount; and a third cover structure arranged over the third LED chip, the third cover structure comprising a third lumiphoric material region that is vertically registered over only a portion of the third LED chip. In certain embodiments: the first LED chip is configured to provide light with a first peak wavelength in a range from 600 nm to 650 nm; the first lumiphoric material region is configured to convert a portion of the first peak wavelength to a second peak wavelength that is different than the first peak wavelength; the second LED chip is configured to provide light with a third peak wavelength in a range from 500 nm to 570 nm; the second lumiphoric material region is configured to convert a portion of the third peak wavelength to a fourth peak wavelength that is different than the third peak wavelength; the third LED chip is configured to provide light with a fifth peak wavelength in a range from 430 nm to 480 nm; and the third lumiphoric material region is configured to convert a portion of the fifth peak wavelength to a sixth peak wavelength that is different than the fifth peak wavelength. In certain embodiments, the second peak wavelength, the fourth peak wavelength, and the sixth peak wavelength are all different from one another. In certain embodiments, the first peak wavelength, the second peak wavelength, the third peak wavelength, the fourth peak wavelength, the fifth peak wavelength and the sixth peak wavelength are all spaced at least 10 nm from one another within a range from 430 nm to 650 nm. In certain embodiments, the first lumiphoric material region comprises a plurality of discrete portions that forms a repeating pattern across the first cover structure. In certain embodiments, the first lumiphoric material region comprises a plurality of discrete portions that forms a random pattern across the first cover structure.

In another aspect, an LED package comprises: a submount; an LED chip on the submount, the LED chip comprising a first light-emitting junction and a second light-emitting junction; and a cover structure arranged over the LED chip, the cover structure comprising a first lumiphoric material region that is patterned over a portion of the first light-emitting junction. In certain embodiments, the first lumiphoric material region occupies a first lateral area of the first-light emitting junction that is less than a second lateral area of the first light-emitting junction. The LED package may further comprise a second lumiphoric material region that is patterned over a portion of the second light-emitting junction, wherein: the LED chip is configured to emit a first peak wavelength; the first lumiphoric material region is configured to convert a portion of the first peak wavelength to a second peak wavelength; the second lumiphoric material region is configured to convert a portion of the first peak wavelength to a third peak wavelength; and the first peak wavelength, the second peak wavelength, and the third peak wavelength are all different from one another. In certain embodiments: the LED chip comprises a third light-emitting junction; and the cover structure is devoid of any lumiphoric material that is vertically registered with the third light-emitting junction. In certain embodiments, the first lumiphoric material region comprises a plurality of discrete portions that forms a repeating pattern or a random pattern across the cover structure

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing FIGURES.

### BRIEF DESCRIPTION OF THE DRAWING FIGURES

The accompanying drawing FIGURES incorporated in and forming a part of this specification illustrate several aspects of the disclosure, and together with the description serve to explain the principles of the disclosure.

FIG. 1 is a cross-sectional view of a light-emitting diode (LED) package that includes an LED chip and a cover structure with one or more discrete lumiphoric material regions positioned over a portion of the LED chip.

FIG. 2 is a cross-sectional view of an LED package that is similar to the LED package of FIG. 1 and where the lumiphoric material region is patterned in a plurality of discrete portions across a support element.

FIG. 3 is a cross-sectional view of an LED package that is similar to the LED package of FIG. 1 for embodiments that include multiple LED chips.

FIG. 4 is a cross-sectional view of an LED package that is similar to the LED package of FIG. 3 except the pattern of the lumiphoric material regions is different for different LED chips.

FIG. 5 is a cross-sectional view of an LED package that is similar to the LED package of FIG. 3 and where multiple LED chips are provided with cover structures that have different types of lumiphoric material regions.

FIG. 6 is a cross-sectional view of an LED package that is similar to the LED package of FIG. 5 for arrangements where one or more of the lumiphoric material regions may be patterned in a similar manner as illustrated in FIG. 2.

FIG. 7 is a cross-sectional view of an LED package that is similar to the LED package of FIG. 1 for examples where the LED chip embodies a multiple-junction LED chip.

FIG. 8 is a cross-sectional view of an LED package that is similar to the LED package of FIG. 7 and where at least one light-emitting junction is not covered by a corresponding lumiphoric material region.

FIGS. 9A to 9C are cross-sectional views of an LED package that is similar to the LED package of FIG. 1 and further illustrate various positions of a shutter that is configured to selectively cover or uncover various portions of the LED chip to provide different emission characteristics.

### DETAILED DESCRIPTION

The embodiments set forth below represent the necessary information to enable those skilled in the art to practice the embodiments and illustrate the best mode of practicing the embodiments. Upon reading the following description in light of the accompanying drawing FIGURES, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the FIGURES. It will be understood that these terms and those discussed above are intended to encompass different orientations of the device in addition to the orientation depicted in the FIGURES.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between FIGURES may be shown herein with common element numbers and may not be subsequently re-described.

The present disclosure relates to solid-state lighting devices including light-emitting diodes (LEDs), and more particularly to lumiphoric material arrangements for cover structures of packaged LED devices. Lumiphoric material arrangements include discrete regions of lumiphoric materials that are provided over portions of underlying LED chips. The discrete regions of lumiphoric materials may be patterned on portions of cover structures that are then attached to underlying LED chips. By having discrete regions of lumiphoric materials over portions of LED chips, certain emissions from the LED chips may pass through the lumiphoric materials while other emissions from the LED chips may be emitted without passing through the lumiphoric materials. In this manner, contributions of the lumiphoric materials to aggregate emissions of LED packages may provide increased spectral bandwidth. The ability to provide patterns of lumiphoric materials on cover structures provides increased control of intensity and/or spatial position of the lumiphoric materials relative to the aggregate emissions.

Before delving into specific details of various aspects of the present disclosure, an overview of various elements that may be included in exemplary LED packages of the present disclosure is provided for context. An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure can comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements. The active layer can comprise a single quantum well, a multiple quantum well, a double heterostructure, or super lattice structures.

The active LED structure can be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). Other material systems include silicon carbide (SiC), organic semiconductor materials, and other Group III-V systems such as gallium phosphide (GaP), gallium arsenide (GaAs), and related compounds.

The active LED structure may be grown on a growth substrate that can include many materials, such as sapphire, SiC, aluminum nitride (AlN), and GaN. SiC has certain advantages, such as a closer crystal lattice match to Group III nitrides than other substrates and results in Group III nitride films of high quality. SiC also has a very high thermal conductivity so that the total output power of Group III nitride devices on SiC is not limited by the thermal dissipation of the substrate. Sapphire is another common substrate for Group III nitrides and also has certain advantages, including being lower cost, having established manufacturing processes, and having good light-transmissive optical properties.

Different embodiments of the active LED structure can emit different wavelengths of light depending on the composition of the active layer and n-type and p-type layers. In some embodiments, the active LED structure emits blue light with a peak wavelength range of approximately 430 nanometers (nm) to 480 nm. In other embodiments, the active LED structure emits green light with a peak wavelength range of 500 nm to 570 nm. In other embodiments, the active LED structure emits red light with a peak wavelength range of 600 nm to 650 nm. In certain embodiments, the active LED structure may be configured to emit light that is outside the visible spectrum, including one or more portions of the UV spectrum. The UV spectrum is typically divided into three wavelength range categories denotated with letters A, B, and C. In this manner, UV-A light is typically defined as a peak wavelength range from 315 nm to 400 nm, UV-B is typically defined as a peak wavelength range from 280 nm to 315 nm, and UV-C is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications.

Light emitted by the active layer or region of an LED chip may typically travel in a variety of directions. For targeted directional applications, internal mirrors or external reflective surfaces may be employed to redirect as much light as possible toward a desired emission direction. Internal mirrors may include single or multiple layers. Some multi-layer mirrors include a metal reflector layer and a dielectric reflector layer, wherein the dielectric reflector layer is arranged between the metal reflector layer and a plurality of semiconductor layers. A passivation layer is arranged between the metal reflector layer and first and second electrical contacts, wherein the first electrical contact is arranged in conductive electrical communication with a first semiconductor layer, and the second electrical contact is arranged in conductive electrical communication with a second semiconductor layer. For single or multi-layer mirrors including surfaces exhibiting less than 100% reflectivity, some light may be absorbed by the mirror. Additionally, light that is redirected through the active LED structure may be absorbed by other layers or elements within the LED chip.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In the case of UV LEDs, appropriate materials may be selected to provide a desired, and in some embodiments high, reflectivity and/or a desired, and in some embodiments low, absorption. In certain embodiments, a “light-transmissive” material may be configured to transmit at least 50% of emitted radiation of a desired wavelength.

The present disclosure may be useful for LED chips having a variety of geometries, including flip-chip geometries. Flip-chip structures for LED chips typically include anode and cathode connections that are made from a same side or face of the LED chip. The anode and cathode side is typically structured as a mounting face of the LED chip for flip-chip mounting to another surface, such as a printed circuit board. In this regard, the anode and cathode connections on the mounting face serve to mechanically bond and electrically couple the LED chip to the other surface. When flip-chip mounted, the opposing side or face of the LED chip corresponds with a light-emitting face that is oriented toward an intended emission direction. In certain embodiments, a growth substrate for the LED chip may form and/or be adjacent to the light-emitting face when flip-chip mounted. During chip fabrication, the active LED structure may be epitaxially grown on the growth substrate.

According to aspects of the present disclosure, LED packages may include one or more elements, such as lumiphoric materials or phosphors for wavelength conversion, cover structures, encapsulants, light-altering materials, lenses, and electrical contacts, among others, that are provided with one or more LED chips. In certain aspects, an LED package may include a support structure or member, such as a submount or a lead frame. A support structure may refer to a structure of an LED package that supports one or more other elements of the LED package, including but not limited to LED chips and cover structures. In certain embodiments, a support structure may include a submount on which an LED chip is mounted. Suitable materials for a submount include, but are not limited to, ceramic materials such as aluminum oxide or alumina, AlN, or organic insulators like polyimide (PI) and polyphthalamide (PPA). In other embodiments a submount may comprise a printed circuit board (PCB), sapphire, Si, or any other suitable material. For PCB embodiments, different PCB types can be used such as standard FR-4 PCB, metal core PCB, or any other type of PCB. In still further embodiments, the support structure may embody a lead frame structure. Aspects of the present disclosure are provided in the context of support structures for LED chips that may emit light in any number of wavelength ranges, including wavelengths within UV and/or visible light spectrums.

Light-altering materials may be arranged within LED packages to reflect or otherwise redirect light from the one or more LED chips in a desired emission direction or pattern. As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, scatter, or otherwise redirect light. For light-reflective materials, the light-altering material may include at least one of fused silica, fumed silica, titanium dioxide (TiO₂), or metal particles suspended in a binder, such as silicone or epoxy. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque or black color for absorbing light and increasing contrast.

An LED chip can also be covered or otherwise arranged to emit light toward one or more lumiphoric materials (also referred to herein as lumiphores), such as phosphors, such that at least some of the light from the LED chip is absorbed by the one or more lumiphores and is converted to one or more different wavelength spectra according to the characteristic emission from the one or more lumiphores. In this regard, at least one lumiphore receiving at least a portion of the light generated by the LED source may re-emit light having different peak wavelength than the LED source. An LED source and one or more lumiphoric materials may be selected such that their combined output results in light with one or more desired characteristics such as color, color point, intensity, etc. In certain embodiments, aggregate emissions of LED chips, optionally in combination with one or more lumiphoric materials, may be arranged to provide cool white, neutral white, or warm white light, such as within a color temperature range of from 2500 Kelvin (K) to 10,000K. In certain embodiments, lumiphoric materials having cyan, green, amber, yellow, orange, and/or red peak wavelengths may be used. In some embodiments, the combination of the LED chip and the one or more lumiphores (e.g., phosphors) emits a generally white combination of light. The one or more phosphors may include yellow (e.g., YAG:Ce), green (e.g., LuAg:Ce), and red (e.g., Ca_{i-x-y}SrₓEu_{y}AlSiN₃) emitting phosphors, and combinations thereof.

Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces, dispersal in an encapsulant material, and/or coating on one or more optical or support elements (e.g., by powder coating, inkjet printing, spray coating or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. In certain embodiments, one or more lumiphoric materials may be arranged on or over one or more surfaces of an LED chip in a substantially uniform manner. In other embodiments, one or more lumiphoric materials may be arranged on or over one or more surfaces of an LED chip in a manner that is non-uniform with respect to one or more of material composition, concentration, and thickness. In certain embodiments, the loading percentage of one or more lumiphoric materials may be varied relative to one or more outer surfaces of an LED chip. In certain embodiments, one or more lumiphoric materials may be patterned relative to one or more surfaces of an LED chip to include one or more stripes, dots, curves, or polygonal shapes. In certain embodiments, multiple lumiphoric materials may be arranged in different discrete regions or discrete layers on or over an LED chip.

In certain embodiments, one or more lumiphoric materials may be provided as at least a portion of a wavelength conversion element or cover structure for an LED package. Wavelength conversion elements or cover structures may include a support element, such as a superstrate, and one or more lumiphoric materials that are provided by any suitable means, such as by coating a surface of the superstrate or by incorporating within the superstrate. The term “superstrate” as used herein refers to an element placed on or over an LED chip that may include a lumiphoric material. The term “superstrate” is used herein, in part, to avoid confusion with other substrates that may be part of the semiconductor light-emitting device, such as a growth or carrier substrate of the LED chip or a submount of an LED package. The term “superstrate” is not intended to limit the orientation, location, and/or composition of the structure it describes. In some embodiments, the superstrate may be composed of a transparent material, a semi-transparent material, or a light-transmissive material, such as sapphire, SiC, silicone, and/or glass (e.g., borosilicate and/or fused quartz). Superstrates may be formed from a bulk substrate which is optionally patterned and then singulated. In certain embodiments, superstrates may comprise a generally planar upper surface that corresponds to a light emission area of the LED package.

One or more lumiphoric materials may be arranged on the superstrate by, for example, spraying and/or otherwise coating the superstrate with the lumiphoric materials. Wavelength conversion elements may be attached to one or more LED chips using, for example, a layer of transparent adhesive. In certain embodiments, the layer of the transparent adhesive may include silicone with a refractive index in a range of about 1.3 to about 1.6 that is less than a refractive index of the LED chip on which the wavelength conversion element is placed. In other embodiments, wavelength conversion elements may comprise alternative configurations, such as phosphor-in-glass or ceramic phosphor plate arrangements. Phosphor-in-glass or ceramic phosphor plate arrangements may be formed by mixing phosphor particles with glass frit or ceramic materials, pressing the mixture into planar shapes, and firing or sintering the mixture to form a hardened structure that can be cut or separated into individual wavelength conversion elements.

LED packages may include one or more LED chips and one or more lumiphoric materials arranged together to provide aggregate emissions across a range of emission wavelengths. In certain embodiments, specific arrangements of lumiphoric materials along with LED chips may provide aggregate emissions targeted for particular lighting applications where increased color saturation, color rendering, and/or gamut are desired.

Color reproduction is commonly measured using Color Rendering Index (CRI) or average Color Rendering Index (CRI Ra). CRI and CRI Ra are used to determine how closely an artificial light source, such as LED light sources, matches the color rendering of a natural light source at the same correlated color temperature. CRI Ra (or CRI) alone may not provide a complete measure of the benefit of a light source, since it confers little ability to predict color discrimination (i.e., to perceive subtle difference in hue) or color preference. Daylight provides a spectrum of light that allows the human eye to perceive bright and vivid colors, which allows objects to be distinguished even with subtle color shade differences. The ability of human vision to differentiate color is different under correlated color temperature conditions providing the same CRI Ra. Such differentiation is proportional to the gamut of the illuminating light. Gamut area of a light source can be calculated as the area enclosed within a polygon defined by the chromaticities in CIE 1976 u′v′ color space of the eight color chips used to calculate CRI Ra when illuminated by a test light source. Gamut area index (GAI) is a convenient way of characterizing in chromaticity space how saturated the illumination makes objects appear—with a larger GAI making object colors appear more saturated.

According to various aspects of the present disclosure, LED packages may be readily tailored to target various color rendering and/or color gamut characteristics by select placement of lumiphoric material regions for cover structures relative to LED chips. In particular embodiments, cover structures with one or more discrete lumiphoric material regions and one or more transparent regions may be selectively placed over a common LED chip. In this manner, the one or more discrete lumiphoric material regions may only partially cover the LED chip so that certain light paths from the LED chip will travel through the lumiphoric material regions and be subject to wavelength conversion while other light paths from the LED chip may directly travel through the transparent regions. Such arrangements may be advantageous for increasing a gamut of a single LED chip. For example, an LED chip may be configured to emit a blue peak wavelength in a range from 430 nm to 480 nm and the discrete lumiphoric material region may be configured to provide a longer peak wavelength, such as cyan or green wavelengths in a range from 480 nm to 570 nm. As the human eye is typically more sensitive to cyan and green wavelengths than blue wavelengths, relatively small contributions of discrete lumiphoric material regions may allow the aggregate emissions to appear brighter. Additionally, the aggregate emissions will have a broader spectrum than a standard monochromatic LED emitter. By providing the discrete lumiphoric material regions on a cover structure, precise control of the location and/or size may be achieved to target specific color points and/or emission spectrums. In contrast, conventional lumiphoric coatings on LED chips that are blanket deposited may exhibit color over angle nonuniformity when targeting such aggregate emissions. In other embodiments, cover structures may include combinations of multiple lumiphoric material regions and one or more transparent regions over various junctions of a monolithic LED chip.

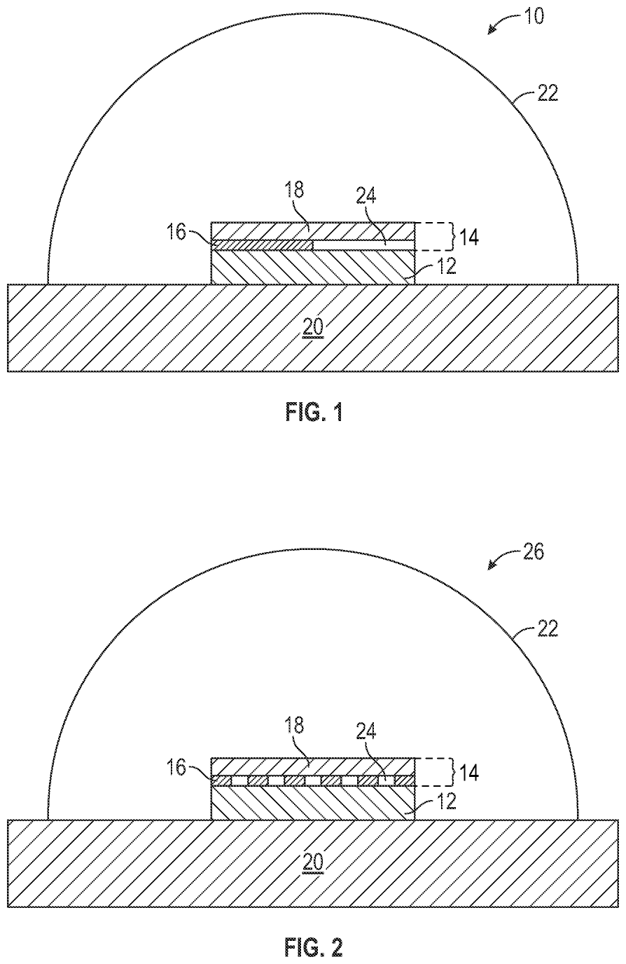

FIG. 1 is a cross-sectional view of an LED package 10 that includes an LED chip 12 and a cover structure 14 with one or more discrete lumiphoric material regions 16 positioned over a portion of the LED chip 12. The lumiphoric material region 16 may be arranged on a support element 18, or superstrate, of the cover structure 14. As illustrated, the LED package 10 may further include a submount 20 on which the LED chip 12 is mounted and an encapsulant 22 that encloses the LED chip 12 and cover structure 14. The support element 18 may comprise materials that are light-transparent or light-transmissive to wavelengths provided by the LED chip 12 and the lumiphoric material region 16. Exemplary materials for the support element 18 include glass, sapphire, SiC, and hardened silicone, among others. The lumiphoric material region 16 may be formed on the support element 18 before the cover structure 14 is attached or otherwise mounted on the LED chip 12. In certain embodiments, a light-transparent adhesive, such as silicone or epoxy, may be used to attach the cover structure 14 to the LED chip 12. By first forming the lumiphoric material region 16 on the support element 18 before the cover structure 14 is attached, the amount and/or location of the lumiphoric material region 16 may be tailored to a particular application. The lumiphoric material region 16 may form a pattern on the support element 18, such as the pattern illustrated in FIG. 1 or additional patterns as described later. For illustrative purposes, the lumiphoric material region 16 is shown in FIG. 1 as occupying about half of the bottom surface of the support element 18. In certain embodiments, the lumiphoric material region 16 may occupy a range from 1% to 90%, or a range from 1% to 75%, or a range from 1% to 50% of the bottom surface of the support element 18 depending on the desired aggregate emissions for the LED package 10.

The lumiphoric material region 16 may be arranged to be vertically registered with only a first portion of the LED chip 12. In this manner, aggregate emissions for the LED package 10 may include light with a first peak wavelength generated by the LED chip 12 and light with a second peak wavelength that is provide by wavelength conversion in the lumiphoric material region 16. By only covering a portion of the LED chip 12 and not the entire top face, contributions from the lumiphoric material region 16 may be precisely controlled to increase a color gamut while still having aggregate emissions close to a target wavelength. As described above, an exemplary configuration may include the LED chip 12 being configured to emit a blue peak wavelength in a range from 430 nm to 480 nm, and the discrete lumiphoric material region may be configured to provide a longer peak wavelength, such as cyan or green wavelengths in a range from 480 nm to 570 nm. As such, aggregate emissions for the LED package 10 may still include a peak wavelength in the blue range with increased bandwidth into the 480 nm to 570 nm range for increased color gamut and/or increased perceived brightness.

In certain embodiments, portions of the support element 18 that are not covered by the lumiphoric material region 16 may include a transparent material region 24, such as silicone or glass, that is devoid of lumiphoric materials. The transparent material region 24 may be provided on the bottom surface of the support element 18 in a laterally adjacent position to the lumiphoric material region 16. In certain embodiments, a surface of the transparent material region 24 that is proximate the LED chip 12 may be coplanar with a surface of the lumiphoric material region 16 that is also proximate the LED chip 12. This may provide a substantially planar surface of the cover structure 14 to facilitate more even mounting with the LED chip 12.

FIG. 2 is a cross-sectional view of an LED package 26 that is similar to the LED package 10 of FIG. 1 and where the lumiphoric material region 16 is patterned in a plurality of discrete portions across the support element 18. In this manner, the lumiphoric material region 16 may be more evenly distributed across the cover structure 14 to provide more even color mixing in the aggregate emissions. In certain embodiments, the plurality of discrete portions of the lumiphoric material region 16 may form a repeating pattern across the cover structure 14. In other embodiments, the plurality of discrete portions of the lumiphoric material region 16 may form a random pattern across the cover structure 14. The selection of pattern type may be determined based on targeted aggregate emissions for the LED package 26. Since the pattern of the lumiphoric material region 16 is provided for the cover structure 14 before attachment, increased flexibility in the design of repeating and/or random patterns may be achieved as compared with conventional lumiphoric material coatings. A number of the transparent material regions 24 may be arranged to cover portions of the support element 18 that are uncovered by the lumiphoric material region 16 in a similar manner as described above for FIG. 1.

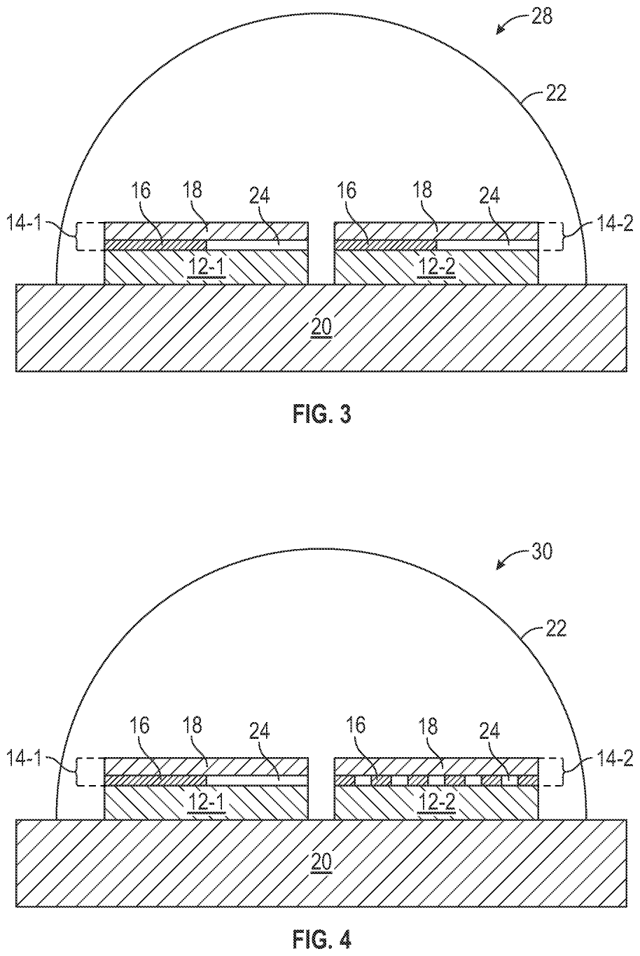

FIG. 3 is a cross-sectional view of an LED package 28 that is similar to the LED package 10 of FIG. 1 for embodiments that include multiple LED chips 12-1, 12-2. As illustrated, the arrangement of the LED chips 12-1, 12-2 and cover structures 14-1, 14-2 may be similar to FIG. 1 and repeated across the submount 20 to form a multiple-chip array within the same LED package 28. The array of the LED chips 12-1, 12-2 and corresponding cover structures 14-1, 14-2 may be provided under the common encapsulant 22 or lens for higher intensity emissions. In certain embodiments, the spacing between the LED chips 12-1, 12-2 may be close enough that the multiple LED chips 12-1, 12-2 appear as a continuous light-emitting surface within the LED package 28. Additionally, the lumiphoric material regions 16 may accordingly be formed in discrete regions across the continuous light-emitting surface for improved color mixing and/or uniformity. The lumiphoric material regions 16 of the cover structures 14-1, 14-2 may include a same type of lumiphoric material that provides a same peak wavelength for wavelength conversion, thereby contributing to the appearance of the continuous light-emitting surface.

FIG. 4 is a cross-sectional view of an LED package 30 that is similar to the LED package 28 of FIG. 3 except the pattern of the lumiphoric material regions 16 is different for different LED chips 12-1, 12-2. By way of example, the cover structure 14-1 for the LED chip 12-1 may have the lumiphoric material region 16 as described above for FIG. 1 while the cover structure 14-2 for the LED chip 12-2 may have the lumiphoric material region 16 as described above for FIG. 2. This provides the flexibility to tailor emission patterns locally across the LED package 30 based on proximity to the lens 22 and/or adjacent ones of the LED chips 12-1, 12-2.

In certain aspects, the principles of the present disclosure are readily applicable to multiple chip and multiple color applications where LED chips of different emission colors are arranged with cover structures as described above. In the context of red-green-blue, or RGB, LED packages, cover structures with discrete lumiphoric material regions as described above may be provided to increase the color gamut while also providing suitable wavelengths in the red, green, and blue spectrums. By using discrete lumiphoric material regions in cover structures instead of additional LED chips of other colors, emission spectrum gaps between monochromatic emissions of LED chips may be precisely controlled with reduced efficiency losses. For example, increasing color gamut with additional LED chips of different colors may increase a number of drive voltages associated with the additional LED chips.

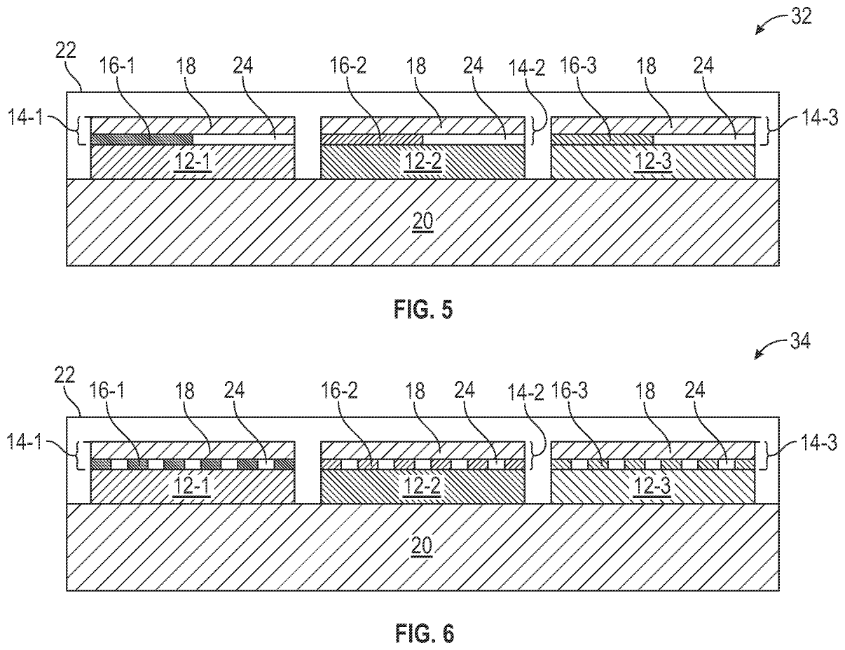

FIG. 5 is a cross-sectional view of an LED package 32 that is similar to the LED package 28 of FIG. 3 and where multiple LED chips 12-1 to 12-3 are provided with cover structures 14-1 to 14-3 that have different types of lumiphoric material regions 16-1 to 16-3. Remainders of the cover structures 14-1 to 14-3 may be occupied by transparent material regions 24 as described above for FIG. 1. In certain embodiments, the LED chips 12-1 to 12-3 may be configured to emit different peak wavelengths, such as red, green, and blue for RGB applications. The ability to provide discrete lumiphoric material regions 16-1 to 16-3 over portions of the LED chips 12-1 to 12-3 allows spectral gaps between monochromatic emissions of the LED chips 12-1 to 12-3 to be filled by the lumiphoric material regions 16-1 to 16-3 without significantly altering the RGB emissions and/or having to add additional LED chips of different colors.

By way of example, the first LED chip 12-1 may be configured to emit red light, such as a first peak wavelength in a range from 600 nm to 650 nm, and the corresponding first lumiphoric material region 16-1 may be configured to convert a portion of the first peak wavelength to a second peak wavelength that is also in a range from 600 nm to 650 nm but is different from the first peak wavelength. In this manner, the first LED chip 12-1 and the first lumiphoric material region 16-1 may collectively provide two different peak wavelengths in the range from 600 nm to 650 nm, effectively increasing the color gamut compared with the first LED chip 12-1 by itself. In other embodiments, the second peak wavelength may be in a range that is below 600 nm to fill in other spectral gaps. By providing the first lumiphoric material region 16-1 as a pattern of the cover structure 14-1 that resides over only a portion of the LED chip 12-1, the amount of spectral contribution from the first lumiphoric material region 16-1 may be precisely controlled. For example, the combination of light from the first lumiphoric material region 16-1 and the first LED chip 12-1 may predominantly be light from the first LED chip 12-1 with the first peak wavelength while a suitable amount of light from the first lumiphoric material region 16-1 with the second peak wavelength may contribute to the increased spectral bandwidth. In a similar manner, the second LED chip 12-2 may be configured to emit green light with a third peak wavelength in a range from 500 nm to 570 nm, and the second lumiphoric material region 16-2 may be configured to convert a portion of the third peak wavelength to light of a fourth peak wavelength that is different than the third peak wavelength, such as different peak wavelength in the 500 nm to 570 nm range, or a peak wavelength below 500 nm or above 570 nm to fill certain spectral gaps. Finally, the third LED chip 12-3 may be configured to emit green light with a fifth peak wavelength in a range from 430 nm to 480 nm, and the third lumiphoric material region 16-3 may be configured to convert a portion of the fifth peak wavelength to light of a sixth peak wavelength that is different than the fifth peak wavelength, such as different peak wavelength in the 430 nm to 480 nm range, or a peak wavelength above 480 nm to fill certain spectral gaps

In a particular example, the first through sixth peak wavelengths may all be different values. For example, the first through sixth peak wavelengths may be separated from their closest wavelength neighbors by 10 nm to 30 nm within a range from 430 nm to 650 nm to effectively increase spectral bandwidth without adding additional LED chips.

FIG. 6 is a cross-sectional view of an LED package 34 that is similar to the LED package 32 of FIG. 5 for arrangements where one or more of the lumiphoric material regions 16-1 to 16-3 may be patterned in a similar manner as illustrated in FIG. 2. In this manner, one or more of the lumiphoric material regions 16-1 to 16-3 may be patterned in a repeating manner or in a random manner along the respective support elements 18 of the cover structures 14-1 to 14-3. As described above, the ability to tailor specific patterns of any of the lumiphoric material regions 16-1 to 16-3 and/or the transparent material regions 24 allows precise control of spectral bandwidths for targeted color gamuts.

In certain aspects, the principles of the present disclosure are readily applicable to multiple-junction LED chips. As defined herein, a multiple-junction LED chip may also be referred to as a monolithic LED chip. Multiple-junction LED chips typically include multiple light-emitting junctions that are formed on and supported by a common layer or a substrate. In this manner, a single LED chip may be referred to as a multiple-junction LED chip when multiple light-emitting junctions are arranged on a common layer or substrate of the single LED chip. The multiple light-emitting junctions may be electrically isolated from one another while also being formed from a common LED epitaxial structure. In certain aspects, a common layer, when present, may be provided by a common epitaxial layer that is continuous across the multiple light-emitting junctions. In certain aspects, a common substrate may be provided by a common growth substrate on which the epitaxial structure is initially formed, where the common growth substrate is continuous across the multiple light-emitting junctions. Such multiple-junction arrangements with discrete lumiphoric material regions may be well suited for high-powered directional lighting, such as stage lighting, where multiple emission colors may be selected while reducing the need for complex diffusers and/or optics for mixing multiple colors of light.

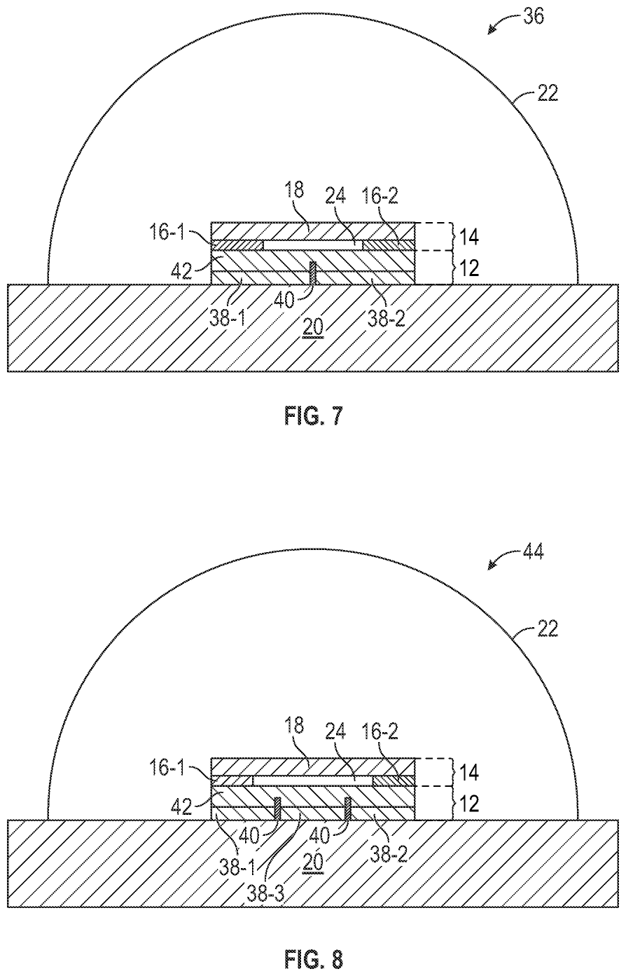

FIG. 7 is a cross-sectional view of an LED package 36 that is similar to the LED package 10 of FIG. 1 for examples where the LED chip 12 embodies a multiple-junction LED chip. In FIG. 7, the LED chip 12 may be divided into separate light-emitting junctions 38-1, 38-2 that are separated by a divider 40 therebetween. A common layer 42, such as a portion of a growth substrate and/or an epitaxial layer may be continuous between the light-emitting junctions 38-1, 38-2. The divider 40 may include a gap that is formed through electrically conductive portions of the LED chip 12 to electrically isolate the light-emitting junctions 38-1, 38-2 from one another. In this manner, the light-emitting junctions 38-1, 38-1 may be individually addressable. The cover structure 14 may be continuous across the LED chip 12, thereby covering the light-emitting junctions 38-1, 38-2. As described above, the ability to pattern discrete lumiphoric material regions 16-1, 16-2 on select portions of the support element 18 provides the ability to tailor spectral emissions and/or fill in spectral gaps of emissions from the light-emitting junctions 38-1, 38-2. In certain embodiments, each of the lumiphoric material regions 16-1, 16-2 may occupy an area of the support element 18 that is less than a corresponding area of the respective light-emitting junctions 38-1, 38-2. For example, the first lumiphoric material region 16-1 may occupy a lateral area of the support element 18 that is less than a corresponding lateral area of the light-emitting junction 38-1 as measured horizontally across the submount 20. In certain embodiments, each lumiphoric material region 16-1, 16-2 may occupy a respective area of the support element 18 that is in a range from 1% to 90%, or a range from 1% to 75%, or a range from 1% to 50% of a portion of the bottom surface of the support element 18 that is registered with a corresponding one of the light-emitting junctions 38-1, 38-2. In this manner, some light from each of the light-emitting junctions 38-1, 38-2 may pass through the respective lumiphoric material regions 16-1, 16-2 while other light from each of the light-emitting junctions 38-1, 38-2 may pass directly through the transparent material region 24.

FIG. 8 is a cross-sectional view of an LED package 44 that is similar to the LED package 36 of FIG. 7 and where at least one of the light-emitting junctions 38-1 to 38-3 is not covered by a corresponding lumiphoric material region 16-1 to 16-2. As illustrated, the LED chip 12 may be subdivided to form at least three light-emitting junctions 38-1 to 38-3. The cover structure 14 may be devoid of any lumiphoric material region 16-1, 16-2 that is vertically registered with the light-emitting junction 38-3. In this manner, each of the light-emitting junctions 38-1 to 38-3 may emit a same first peak wavelength, and the lumiphoric material regions 16-1, 16-2 may be arranged to convert more light from their corresponding light-emitting junctions 38-1, 38-2 to light of one or more different wavelengths, thereby allowing most of the light from the light-emitting junction 38-3 to pass freely through the cover structure 14 without wavelength conversion. In a particular example, each of the light-emitting junctions 38-1 to 38-3 may emit blue light while the first lumiphoric material region 16-1 provides red light and the second lumiphoric material region 16-2 provides yellow or green light.

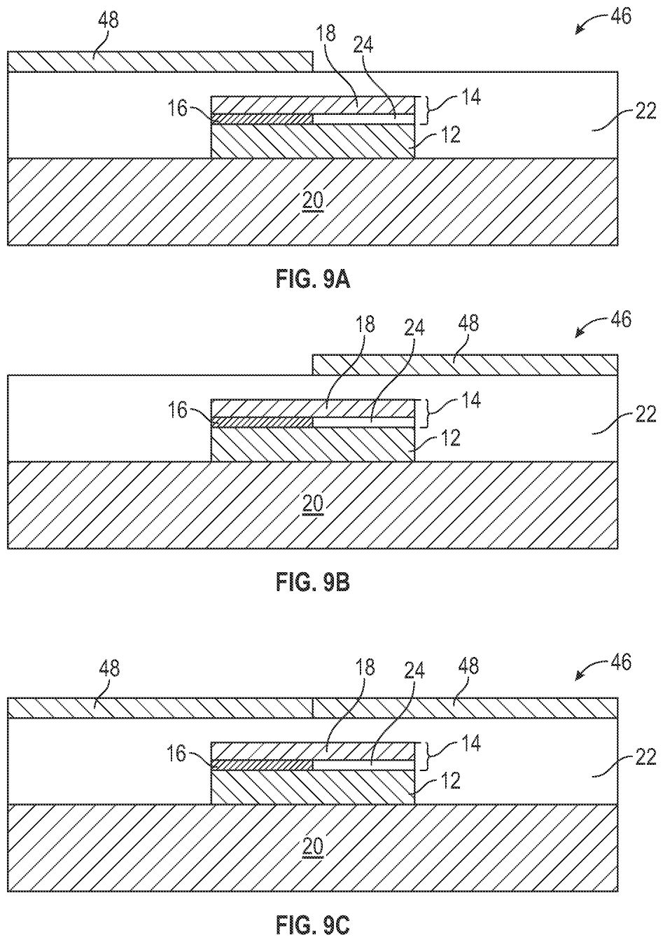

FIGS. 9A to 9C are cross-sectional views of an LED package 46 that is similar to the LED package 10 of FIG. 1 and further includes a shutter 48 that is configured to selectively cover or uncover various portions of the LED chip 12 to provide different emission characteristics. The shutter 48 may embody a mechanical shutter, such as within a flashlight, that controls which portion of the LED chip 12 and cover structure 14 is predominantly providing light that exits the LED package 46. For example, in FIG. 9A, the shutter 48 is arranged to cover the portion of the cover structure 14 that is registered with the lumiphoric material region 16, thereby allowing light from the LED chip 12 that passes through the transparent material region 24 to predominantly exit the LED package 46. In FIG. 9B, the shutter 48 is switched to cover the portion of the cover structure 14 that is registered with the transparent material region 24, thereby allowing light from the LED chip 12 that passes through the lumiphoric material region 16 to predominantly exit the LED package 40. In FIG. 9C, the shutter 48 is arranged to cover the entire cover structure 14. It is further understood that the shutter 48 could also be arranged to uncover both the lumiphoric material region 16 and the transparent material region 24.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) package comprising:
a submount;
an LED chip on the submount, the LED chip comprising a first face and a second face that opposes the first face, the first face being positioned closer to the submount than the second face; and
a cover structure arranged over the LED chip, the cover structure comprising a lumiphoric material region that is vertically registered over a first portion of the LED chip, the first portion of the LED chip comprising a smaller area than the first face of the LED chip.

2. The LED package of claim 1, wherein the cover structure comprises a support element with a top surface and a bottom surface that opposes the top surface, the bottom surface being arranged closer to the LED chip than the top surface, and wherein the lumiphoric material region is arranged on the bottom surface of the support element.

3. The LED package of claim 2, further comprising a transparent material region on portions of the support element that are laterally adjacent the lumiphoric material region.

4. The LED package of claim 3, wherein a surface of the transparent material region that is proximate the LED chip is coplanar with a surface of the lumiphoric material region that is proximate the LED chip.

5. The LED package of claim 2, wherein the lumiphoric material region occupies a range of 1% to 50% of the bottom surface of the support element.

6. The LED package of claim 1, wherein:
the LED chip is configured to provide light with a first peak wavelength in a range from 430 nanometers (nm) to 480 nm; and
the lumiphoric material region is configured to convert a portion of the first peak wavelength to a second peak wavelength that is in a range from 480 nm to 570 nm.

7. The LED package of claim 1, wherein the lumiphoric material region comprises a plurality of discrete portions that forms a repeating pattern across the cover structure.

8. The LED package of claim 1, wherein the lumiphoric material region comprises a plurality of discrete portions that forms a random pattern across the cover structure.

9. The LED package of claim 1, further comprising a shutter that is configured to selectively cover the lumiphoric material region.

10. A light-emitting diode (LED) package comprising:
a submount;
a first LED chip on the submount;
a first cover structure arranged over the first LED chip, the first cover structure comprising a first lumiphoric material region that is vertically registered over only a portion of the first LED chip;
a second LED chip on the submount; and
a second cover structure arranged over the second LED chip, the second cover structure comprising a second lumiphoric material region that is vertically registered over only a portion of the second LED chip.

11. The LED package of claim 10, wherein the first lumiphoric material region and the second lumiphoric material region comprise a same type of lumiphoric material.

12. The LED package of claim 10, wherein the first lumiphoric material region is arranged in a first pattern on the first cover structure and the second lumiphoric material region is arranged in a second pattern on the second cover structure, wherein the first pattern is different than the second pattern.

13. The LED package of claim 10, wherein:
the first LED chip and the second LED chip are configured to provide light with a first peak wavelength in a range from 430 nanometers (nm) to 480 nm;
and the first lumiphoric material region and the second lumiphoric material region are configured to convert a portion of the first peak wavelength to a second peak wavelength that is in a range from 480 nm to 570 nm.

14. The LED package of claim 10, further comprising:
a third LED chip on the submount; and
a third cover structure arranged over the third LED chip, the third cover structure comprising a third lumiphoric material region that is vertically registered over only a portion of the third LED chip.

15. The LED package of claim 14, wherein:
the first LED chip is configured to provide light with a first peak wavelength in a range from 600 nanometers (nm) to 650 nm;
the first lumiphoric material region is configured to convert a portion of the first peak wavelength to a second peak wavelength that is different than the first peak wavelength;
the second LED chip is configured to provide light with a third peak wavelength in a range from 500 nm to 570 nm;
the second lumiphoric material region is configured to convert a portion of the third peak wavelength to a fourth peak wavelength that is different than the third peak wavelength;
the third LED chip is configured to provide light with a fifth peak wavelength in a range from 430 nm to 480 nm; and
the third lumiphoric material region is configured to convert a portion of the fifth peak wavelength to a sixth peak wavelength that is different than the fifth peak wavelength.

16. The LED package of claim 15, wherein the second peak wavelength, the fourth peak wavelength, and the sixth peak wavelength are all different from one another.

17. The LED package of claim 15, wherein the first peak wavelength, the second peak wavelength, the third peak wavelength, the fourth peak wavelength, the fifth peak wavelength and the sixth peak wavelength are all spaced at least nm from one another within a range from 430 nm to 650 nm.

18. The LED package of claim 10, wherein the first lumiphoric material region comprises a plurality of discrete portions that forms a repeating pattern across the first cover structure.

19. The LED package of claim 18, wherein the first lumiphoric material region comprises a plurality of discrete portions that forms a random pattern across the first cover structure.

20. A light-emitting diode (LED) package comprising:
a submount;
an LED chip on the submount, the LED chip comprising a first light-emitting junction and a second light-emitting junction; and
a cover structure arranged over the LED chip, the cover structure comprising a first lumiphoric material region that is patterned over a portion of the first light-emitting junction.

21. The LED package of claim 20, wherein the first lumiphoric material region occupies a first lateral area of the first-light emitting junction that is less than a second lateral area of the first light-emitting junction.

22. The LED package of claim 20, further comprising a second lumiphoric material region that is patterned over a portion of the second light-emitting junction, wherein:
the LED chip is configured to emit a first peak wavelength;
the first lumiphoric material region is configured to convert a portion of the first peak wavelength to a second peak wavelength;
the second lumiphoric material region is configured to convert a portion of the first peak wavelength to a third peak wavelength; and
the first peak wavelength, the second peak wavelength, and the third peak wavelength are all different from one another.

23. The LED package of claim 22, wherein:
the LED chip comprises a third light-emitting junction; and
the cover structure is devoid of any lumiphoric material that is vertically registered with the third light-emitting junction.

24. The LED package of claim 20, wherein the first lumiphoric material region comprises a plurality of discrete portions that forms a repeating pattern or a random pattern across the cover structure.
